(19) United States
(12) Patent Application Publication
(10) Pub. No.: US 2026/0142447 A1
(43) Pub. Date: May 21, 2026

(54) RACK BUSBAR DEVICE AND MANUFACTURING METHOD THEREOF

(71) Applicant: BIZLINK INTERNATIONAL CORP., New Taipei City (TW)

(72) Inventors: Zengshi LAO, New Taipei City (TW); Haoran ZOU, New Taipei City (TW)

(21) Appl. No.: 18/952,948

(22) Filed: Nov. 19, 2024

(51) Int. Cl. H02G 5/06; H02G 5/00; H05K 7/14

(52) U.S. Cl. CPC H02G 5/06; H02G 5/005; H05K 7/1492

(57) ABSTRACT

A rack busbar device includes a housing, a first fastener and an inner assembly. The inner assembly is disposed in the housing and includes two busbars, an insulation bar disposed between and isolating the two busbars, and a second fastener penetrating through the two busbars and the insulation bar to secure the two busbars with the insulation bar. The second fastener is entirely located within the housing. The first fastener penetrates through the housing, the two busbars and the insulation bar to secure the inner assembly inside the housing.

### BACKGROUND

### TECHNICAL FIELD

The present disclosure relates to a rack busbar device and a manufacturing method thereof.

### DESCRIPTION OF RELATED ART

Prior art document US20240212887A1 discloses a busbar assembly including a housing, two busbars and an intermediate insulating member. The busbars and the intermediate insulating member are secured inside the housing by a fastener that passes through the housing, the busbars and the intermediate insulating member. This design makes the busbar assembly difficult to assemble.

### SUMMARY

An aspect of the disclosure is to provide a rack busbar device that is easy to assemble, and to also provide a method of manufacturing the rack busbar device.

In accordance with an embodiment of the present disclosure, a rack busbar device includes a housing, a first fastener and an inner assembly. The inner assembly is disposed in the housing and includes two busbars, an insulation bar disposed between and isolating the two busbars, and a second fastener penetrating through the two busbars and the insulation bar to secure the two busbars with the insulation bar. The second fastener is entirely located within the housing. The first fastener penetrates through the housing, the two busbars and the insulation bar to secure the inner assembly inside the housing.

In accordance with an embodiment of the present disclosure, a method of manufacturing a rack busbar device includes: (a) providing two busbars and an insulation bar between the two busbars; (b) fixedly combine the two busbars and the insulation bar with a second fastener to create an inner assembly, wherein the second fastener penetrates through the two busbars and the insulation bar; and (c) after step (b) is completed, inserting the inner assembly into a housing and affixing the inner assembly to the housing with a first fastener, wherein the first fastener penetrates through the housing, the two busbars and the insulation bar.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates a perspective view of a rack busbar device in accordance with an embodiment of the present disclosure;

FIG. 2 illustrates a sectional view of the rack busbar device shown in FIG. 1 taken along the line segment 2-2’;

FIG. 3 illustrates a sectional view of the rack busbar device shown in FIG. 1 taken along the line segment 3-3’;

FIG. 4 illustrates a sectional view of the rack busbar device shown in FIG. 1 taken along the line segment 4-4’; and

FIG. 5 illustrates a perspective view of one of the insulation ring shown in FIGS. 2 and 3.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

It is noted that all figures of the drawings are drawn according to actual scales. For the conciseness of the specification, the size of each element is not described herein. However, the size and position of each element, as depicted in the drawings, should be considered as being part of the present disclosure.

The present disclosure relates to a rack busbar device (also known as “power rail”) and a manufacturing method thereof. The rack busbar device can be installed on server racks. The rack busbar device is electrically connected to a power source (e.g., a power supply unit (PSU)) to enable power delivery from the power source to one or more servers. The rack busbar device of the present disclosure can be compliant with Open Compute Project (OCP) specifications.

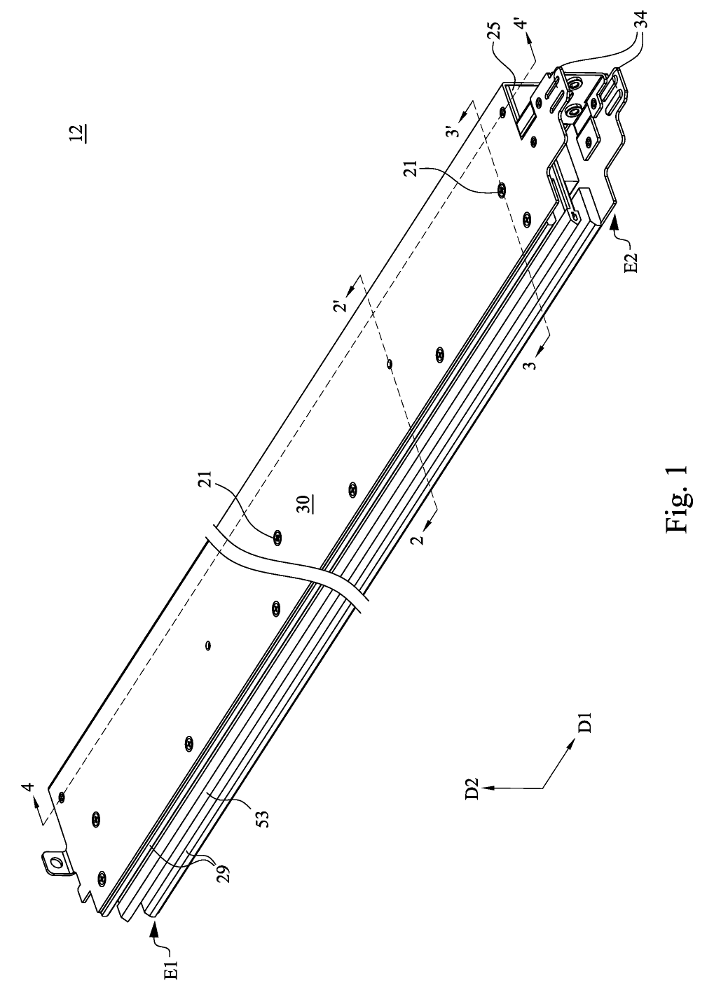

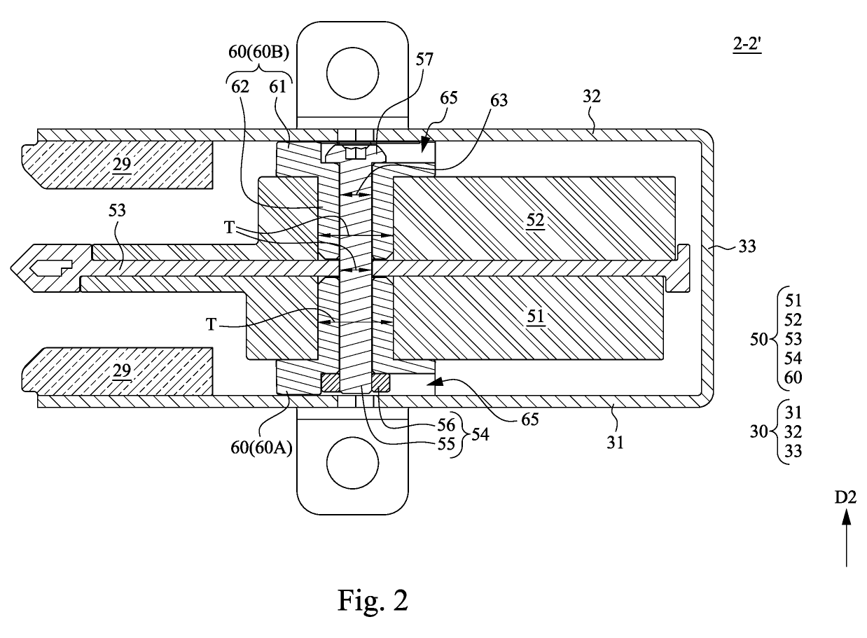

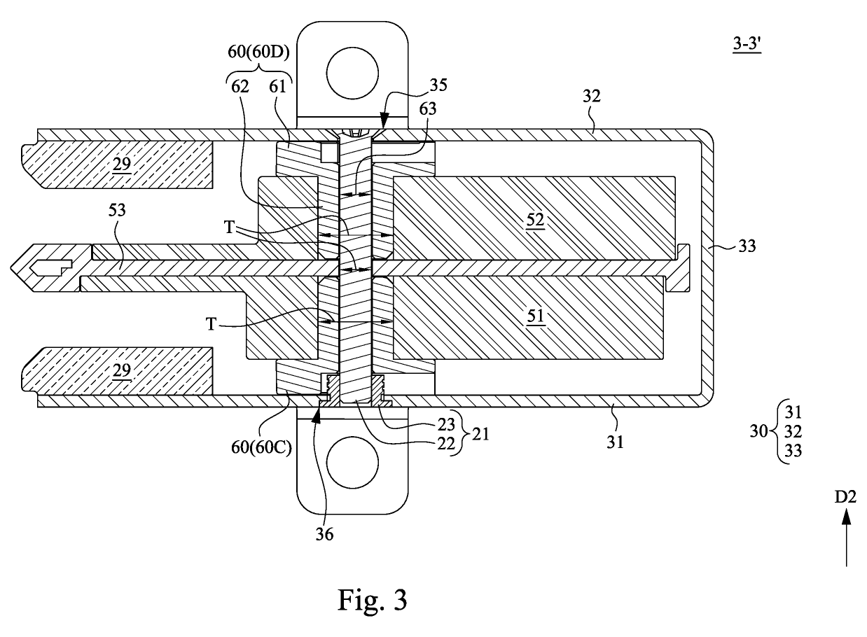

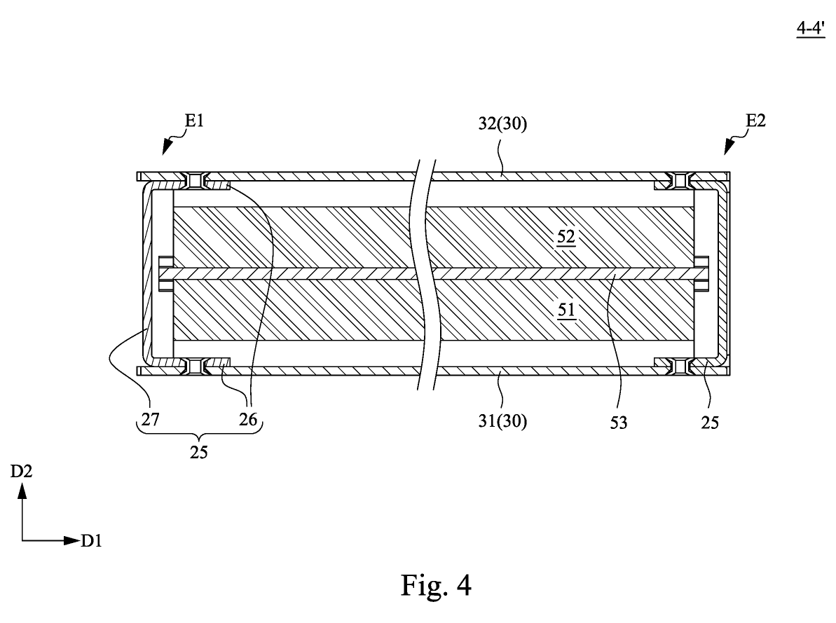

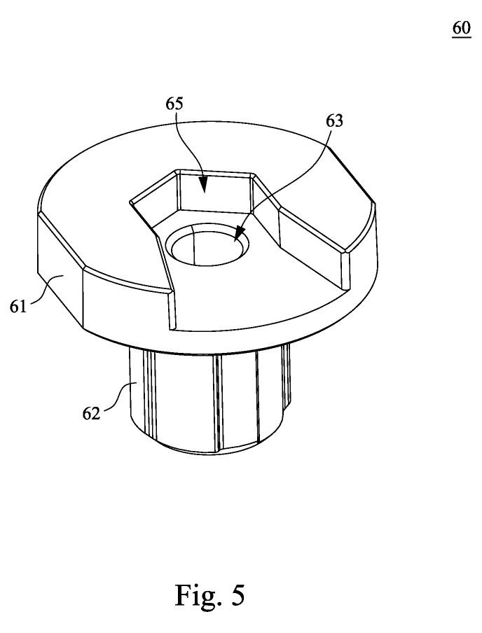

As shown in FIGS. 1-5, a rack busbar device 12 in accordance with an embodiment of the present disclosure includes a housing 30, at least one first fastener 21, at least one bracket 25 and an inner assembly 50. The inner assembly 50 is disposed in the housing 30 and includes two busbars 51 and 52, an insulation bar 53, at least one second fastener 54, and one or more insulation rings 60.

The housing 30 is generally a U-shaped structure and has an elongated shape. The housing 30 may include a first sidewall 31, a second sidewall 32 opposite to the first sidewall 31, and a rear wall 33 connecting the first sidewall 31 and the second sidewall 32. The first sidewall 31 and the second sidewall 32 define an insertion opening that is opposite to the rear wall 33. The insertion opening allows one or more external connectors to be plugged into the housing 30. The housing 30 may be a metallic housing formed of aluminum or other suitable metal material.

The first fastener 21 is used to secure the inner assembly 50 inside the housing 30. The first fastener 21 may include a screw 22 and a nut 23 coupled to a terminal end of the screw 22.

The bracket 25 is generally a U-shaped structure and is affixed to at least one end of the housing 30. The bracket 25 can provide support for the inner assembly 50 and/or maintain the width of the insertion opening of the housing 30. The bracket 25 may be formed of aluminum or other suitable metal material.

The two busbars 51 and 52 include a positive electrode and a negative electrode. The two busbars 51 and 52 are coupled to a power source and are configured to make contact with the external connectors mentioned above to enable power delivery from the power source to one or more servers via the external connectors. The insulation bar 53 is formed of electrically insulated material. The two busbars 51 and 52 and the insulation bar 53 have elongated shapes. The two busbars 51 and 52 and the insulation bar 53 each have a longitudinal direction D1 and a lateral direction D2 traverse to (e.g., normal to) the longitudinal direction D1. The two busbars 51 and 52 and the insulation bar 53 each have at least one thru-hole T.

The second fastener 54 is used to fixedly combine various components of the inner assembly 50, including the two busbars 51 and 52, the insulation bar 53 and the insulation rings 60. The second fastener 54 may include a screw 55 and a nut 56 coupled to a terminal end of the screw 55.

The insulation rings 60 are formed of electrically insulated material. Each of the insulation rings 60 may include a first cylinder 61 and a second cylinder 62. The second cylinder 62 is connected to the first cylinder 61 and has a smaller outer diameter than the first cylinder 61. Each of the insulation rings 60 has a thru-hole 63 that penetrates through the second cylinder 62. The first cylinder 61 may have a recess 65 communicating with the thru-hole 63.

When the inner assembly 50 is assembled, the insulation bar 53 is disposed between and isolates the two busbars 51 and 52 to provide electrical insulation for the two busbars 51 and 52. The thru-holes T of the two busbars 51 and 52 and the insulation bar 53 are aligned with one another in the lateral direction D2. Each of the insulation rings 60 is coupled to a respective thru-hole T of the busbar 51 or the busbar 52. Specifically, the second cylinder 62 is inserted into the thru-hole T and terminates at the insulation bar 53, and the first cylinder 61 is positioned outside the thru-hole T and rests against an outer surface the busbar 51 or the busbar 52. The insulation rings 60 may include a pair of insulation rings 60A and 60B that are lined up in the lateral direction D2 and are separated by the insulation bar 53. In other words, the insulation bar 53 extends through a gap between the second cylinder 62 of the insulation ring 60A and the second cylinder 62 of the insulation ring 60B. The second fastener 54 penetrates through the two busbars 51 and 52, the insulation bar 53 and the insulation rings 60A and 60B to secure the two busbars 51 and 52 with the insulation bar 53 and the insulation rings 60A and 60B. Specifically, the screw 55 of the second fastener 54 passes through the thru-holes 63 of the insulation rings 60A and 60B as well as the thru-hole T of the insulation bar 53. The terminal end of the screw 55 protrudes out of the insulation ring 60A and is joined with the nut 56 of the second fastener 54. A head portion 57 of the screw 55 can be received by the recess 65 of the insulation ring 60B, and the nut 56 may be received by the recess 65 of the insulation ring 60A. The second fastener 54 is thus isolated from the two busbars 51 and 52 by the insulation rings 60A and 60B. The assembled inner assembly 50 can then be placed in the housing 30 and secured inside the housing 30.

Since the various components of the inner assembly 50 are held together by the second fastener 54 before being assembled with the housing 30, the inner assembly 50 can be treated as a single component and can be easily assembled with the housing 30. Accordingly, production of the rack busbar device 12 can be sped up.

When the inner assembly 50 is combined with the housing 30, the various components of the inner assembly 50, including the second fastener 54, are entirely located within the housing 30. The first cylinder 61 of each of the insulation rings 60 is positioned between one of the two busbars 51 and 52 and an inner surface of either sidewall (i.e., the first sidewall 31 or the second sidewall 32) of the housing 30. The first cylinder 61 may make contact with the first sidewall 31 or the second sidewall 32 of the housing 30. Two ends of the second fastener 54 of the inner assembly 50 face the inner surface of the first sidewall 31 and the inner surface of the second sidewall 32, respectively. One end of the second fastener 54 is located between the first sidewall 31 and the busbar 51 (or between the first sidewall 31 and the insulation ring 60A), and another end of the second fastener 54 is located between the second sidewall 32 and the busbar 52 (or between the second sidewall 32 and the insulation ring 60B). In some embodiments, the second fastener 54 is free of contact with the housing 30.

The insulation rings 60 may include a pair of insulation rings 60C and 60D that are lined up in the lateral direction D2 and are separated by the insulation bar 53. In other words, the insulation bar 53 extends through a gap between the second cylinder 62 of the insulation ring 60C and the second cylinder 62 of the insulation ring 60D. The first fastener 21 penetrates through the first sidewall 31 and the second sidewall 32 of the housing 30, the insulation rings 60C and 60D, the two busbars 51 and 52 and the insulation bar 53 to secure the inner assembly 50 inside the housing 30. The first fastener 21 is isolated from the two busbars 51 and 52 by the insulation rings 60C and 60D. In some embodiments, the screw 22 of the first fastener 21 passes through a side opening 35 of the housing 30, the thru-holes 63 of the insulation rings 60C and 60D, and the thru-hole T of the insulation bar 53. The terminal end of the screw 22 protrudes out of the insulation ring 60C and is joined with the nut 23 of the first fastener 21. The nut 23 can be exposed at another side opening 36 of the housing 30.

In some embodiments, the second fastener 54 of the inner assembly 50 has a shorter length than the first fastener 21. In some embodiments, the rack busbar device 12 includes a plurality of first fasteners 21 arranged along a longitudinal direction of the housing 30 (when the inner assembly 50 and the housing 30 are assembled, the longitudinal direction of the housing 30 lines up with the longitudinal direction D1 of the two busbars 51 and 52 and the insulation bar 53). In some embodiments, the inner assembly 50 includes a plurality of second fasteners 54 arranged along the longitudinal direction D1. In some embodiments, the one or more second fasteners 54 of the inner assembly 50 and the one or more first fasteners 21 are arranged in an interleaved manner.

In some embodiments, the housing 30 further includes a joining structure 34. In the longitudinal direction of the housing 30, the housing 30 has a first end E1 and a second end E2 opposite to the first end E1. The joining structure 34 projects from the second end E2 of the housing 30 and has a stepped profile. The stepped profile of the joining structure 34 may include three steps. In other words, the contour line of the joining structure 34 can include three turns. The joining structure 34 facilitates attaching the rack busbar device 12 to a server rack. For example, when the rack busbar device 12 is attached to the server rack, the housing 30 may be positioned vertically, with the first end E1 on the top and the second end E2 at the bottom.

In some embodiments, the bracket 25 includes two bent portions 26 and a base portion 27 connected between the two bent portions 26. The two bent portions 26 are fixedly attached to the inner surface of the first sidewall 31 and the inner surface of the second sidewall 32, respectively. In some embodiments, the rack busbar device 12 includes two brackets 25 that are affixed to the first end E1 and the second end E2 of the housing 30, respectively.

In some embodiments, the rack busbar device 12 further includes a pair of pads 29. The pads 29 are fixedly attached to the first sidewall 31 and the second sidewall 32 of the housing 30, respectively, and are arranged along the sides of the insertion opening of the housing 30. In some embodiments, the pads 29 include ground contacts. In an alternative embodiment, the pads 29 may include electrical insulators.

In accordance with an embodiment of the present disclosure, a method of manufacturing a rack busbar device (e.g., the rack busbar device 12 mentioned above) includes: (a) providing two busbars (e.g., the two busbars 51 and 52 mentioned above) and an insulation bar (e.g., the insulation bar 53 mentioned above) between the two busbars; (b) fixedly combine the two busbars and the insulation bar with a second fastener (e.g., the second fastener 54 mentioned above) to create an inner assembly (e.g., the inner assembly 50 mentioned above), wherein the second fastener penetrates through the two busbars and the insulation bar; and (c) after step (b) is completed, inserting the inner assembly into a housing (e.g., the housing 30 mentioned above) and affixing the inner assembly to the housing with a first fastener (e.g., the first fastener 21 mentioned), wherein the first fastener penetrates through the housing, the two busbars and the insulation bar.

In some embodiments, the method of manufacturing a rack busbar device further includes: inserting a first insulation ring (e.g., the insulation ring 60A mentioned above) into a thru-hole of one of the two busbars; inserting a second insulation (e.g., the insulation ring 60B mentioned above) ring into a thru-hole of another one of the two busbars; and passing the second fastener through the first and second insulation rings, such that the second fastener is isolated from the two busbars by the first insulation ring and the second insulation ring.

In some embodiments, the method of manufacturing a rack busbar device further includes: inserting a first insulation ring (e.g., the insulation ring 60C mentioned above) into a thru-hole of one of the two busbars; inserting a second insulation ring (e.g., the insulation ring 60D mentioned above) into a thru-hole of another one of the two busbars; and passing the first fastener through the first and second insulation rings, such that the first fastener is isolated from the two busbars by the first insulation ring and the second insulation ring.

In some embodiments, the method of manufacturing a rack busbar device further includes: affixing a pair of pads (e.g., the pads 29 mentioned above; the pads can be ground contacts or electrical insulators) to the housing, the pads being arranged along the sides of an insertion opening of the housing. In some embodiments, the method of manufacturing a rack busbar device further includes: affixing at least one bracket (e.g., the bracket 25 mentioned above) to at least one end of the housing, the bracket supporting two sidewalls of the housing. In some embodiments, the pads and the at least one bracket can be affixed to the housing by screw or other suitable types of fasteners.

In sum, the rack busbar device of the present disclosure includes an inner assembly housed by a housing. Various components of the inner assembly, including a pair of busbars arranged side-by-side as well as an insulation bar interposed between the pair of busbars, are held together by a fastener (e.g., a screw and a nut) before being assembled with the housing. The inner assembly can thus be treated as a single component which can be easily assembled with the housing and stably positioned in the housing. Thereafter, another fastener of greater length than the fastener of the inner assembly can be passed through sidewalls of the housing as well as the busbars and the insulation bar of the inner assembly to secure the inner assembly inside the housing. The rack busbar device of the present disclosure has simplified assembly process, resulting in an improvement in productivity.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A rack busbar device, comprising:
a housing;
a first fastener; and
an inner assembly disposed in the housing, the inner assembly comprising two busbars, an insulation bar disposed between and isolating the two busbars, and a second fastener penetrating through the two busbars and the insulation bar to secure the two busbars with the insulation bar, the second fastener is entirely located within the housing;
wherein the first fastener penetrating through the housing, the two busbars and the insulation bar to secure the inner assembly inside the housing.

2. The rack busbar device of claim 1, wherein the housing comprises a first sidewall and a second sidewall opposite to the first sidewall, and two ends of the second fastener face an inner surface of the first sidewall and an inner surface of the second sidewall, respectively.

3. The rack busbar device of claim 2, wherein one end of the second fastener is located between the first sidewall and one of the two busbars, and another end of the second fastener is located between the second sidewall and another one of the two busbars.

4. The rack busbar device of claim 1, wherein the second fastener is free of contact with the housing.

5. The rack busbar device of claim 1, wherein the second fastener has a shorter length than the first fastener.

6. The rack busbar device of claim 1, wherein each of the two busbars has a thru-hole, the inner assembly further comprises at least one insulation ring inserted into the thru-hole, the first fastener or the second fastener extends through the at least one insulation ring and is isolated from the two busbars by the at least one insulation ring.

7. The rack busbar device of claim 6, wherein the at least one insulation ring comprises two insulation rings each coupled to one of the two busbars, each of the two insulation rings comprises a first cylinder and a second cylinder connected to the first cylinder, the first cylinder is positioned between one of the two busbars and an inner surface of the housing, the second cylinder is inserted into the thru-hole and terminates at the insulation bar.

8. The rack busbar device of claim 7, wherein the second fastener comprises a nut and a screw, the first cylinder has a recess receiving the nut or a head portion of the screw.

9. The rack busbar device of claim 1, wherein the housing comprises two sidewalls defining an insertion opening, the rack busbar device further comprises at least one bracket affixed to at least one end of the housing and comprising two bent portions and a base portion, the two bent portions are attached to inner surfaces of the two sidewalls, respectively, and the base portion is connected between the two bent portions.

10. The rack busbar device of claim 9, wherein the at least one bracket comprises two brackets that are affixed to two ends of the housing, respectively.

11. The rack busbar device of claim 1, wherein the housing comprises a joining structure projecting from one end of the housing and having a stepped profile.

12. The rack busbar device of claim 11, wherein the stepped profile of the joining structure comprises three steps.

13. A method of manufacturing a rack busbar device, comprising:
(a) providing two busbars and an insulation bar between the two busbars;
(b) fixedly combine the two busbars and the insulation bar with a second fastener to create an inner assembly, wherein the second fastener penetrates through the two busbars and the insulation bar; and
(c) after step (b) is completed, inserting the inner assembly into a housing and affixing the inner assembly to the housing with a first fastener, wherein the first fastener penetrates through the housing, the two busbars and the insulation bar.

14. The method of claim 13, wherein step (b) comprises:
inserting a first insulation ring into a thru-hole of one of the two busbars;
inserting a second insulation ring into a thru-hole of another one of the two busbars; and
passing the second fastener through the first and second insulation rings, such that the second fastener is isolated from the two busbars by the first and second insulation rings.

15. The method of claim 13, wherein step (c) comprises:
inserting a first insulation ring into a thru-hole of one of the two busbars;
inserting a second insulation ring into a thru-hole of another one of the two busbars; and
passing the first fastener through the first and second insulation rings, such that the first fastener is isolated from the two busbars by the first and second insulation rings.
